(19) United States
(12) Patent Application Publication
(10) Pub. No.: US 2023/0298635 A1
(43) Pub. Date: Sep. 21, 2023

(54) MEMORY DEVICE AND METHOD FOR FORMING SENSE AMPLIFIERS OF MEMORY DEVICE

(71) Applicant: SONIC STAR GLOBAL LIMITED, Tortola (VG)

(72) Inventors: CHENG-CHANG CHEN, Hsinchu County (TW); CHIH-CHIEH CHIU, Hsinchu City (TW); CHUN-YEN LIN, Hualien County (TW)

(21) Appl. No.: 17/696,858

(22) Filed: Mar. 17, 2022

(51) Int. Cl. G11C 7/06

(52) U.S. Cl. CPC G11C 7/065

(57) ABSTRACT

A method for forming sense amplifiers of a memory device includes: determining a type of each bitline selector used to provide a data signal to a corresponding sense amplifier; forming a plurality of separate active areas in a substrate of the memory device along one of a column direction and a row direction according to the type of the bitline selector, the substrate including a plurality of cell columns, each of the cell columns having a plurality of memory cells arranged along the column direction, each of the active areas being formed across a boundary between two adjacent cell columns and located within the adjacent cell columns; and arranging a plurality of gate structures on the active areas to form transistors of the sense amplifiers, each gate structure extending in the row direction.

### BACKGROUND

The present disclosure relates to memory devices and, more particularly, to a layout structure of a sense amplifier of a memory device, and a method for forming sense amplifiers of a memory device.

A sense amplifier is a vital circuit component in the periphery of a memory device as it can sense and amplify voltage signals stored in a selected memory cell. The sense amplifier can mitigate the effects of process variations. For example, a differential sense amplifier is used for noise reduction because of its high common mode rejection ratio. The differential sense amplifier can amplify a small voltage swing to recognizable logic levels, and therefore is suitable for low voltage applications. However, there is a need in the art for an improved design to reduce the adverse effects resulting from the asymmetry in the layout of the sense amplifier and/or the capacitive coupling noise between interconnects.

### SUMMARY

The described embodiments provide a memory device, and a method for forming sense amplifiers of a memory device.

Some embodiments described herein may include a method for forming sense amplifiers of a memory device. The method includes: determining a type of each bitline selector used to provide a data signal to a corresponding sense amplifier; forming a plurality of separate active areas in a substrate of the memory device along one of a column direction and a row direction according to the type of the bitline selector, the substrate including a plurality of cell columns, each of which has a plurality of memory cells arranged along the column direction, each of the active areas being formed across a boundary between two adjacent cell columns and located within the adjacent cell columns; and arranging a plurality of gate structures on the active areas to form transistors of the sense amplifiers, each gate structure extending in the row direction.

Some embodiments described herein may include a memory device. The memory device includes a substrate, a first column of memory cells, a second column of memory cells, a first 1-to-1 multiplexer circuit, a second 1-to-1 multiplexer circuit, and a first sense amplifier. The substrate has a first cell column and a second cell column adjacent to each other. The memory cells of the first column are arranged in the first cell column along a column direction, and are coupled to a first pair of bitlines. The memory cells of the second column are arranged in a second cell column along the column direction, and are coupled to a second pair of bitlines. The first 1-to-1 multiplexer circuit is configured to couple the first pair of bitlines to a first pair of metal lines arranged in the first cell column. The second 1-to-1 multiplexer circuit is configured to couple the second pair of bitlines to a second pair of metal lines arranged in the second cell column. The first sense amplifier is configured to sense a data signal that is carried on the first pair of metal lines. The first sense amplifier includes a first active area formed in the substrate. The first active area extends across a boundary between the first cell column and the second cell column. The first sense amplifier is coupled to the first pair of metal lines via a group of contacts within the first active area.

Some embodiments described herein may include a memory device. The memory device includes a substrate, a first column of memory cells, a second column of memory cells, a third column of memory cells, a fourth column of memory cells, a 4-to-1 multiplexer circuit, and a sense amplifier. The substrate has a first cell column, a second cell column, a third cell column, and a fourth cell column arranged in parallel. The first cell column is adjacent to the second cell column, and the third cell column is adjacent to the fourth cell column. The memory cells of the first column are arranged in the first cell column, and are coupled to a first pair of bitlines. The memory cells of the second column are arranged in the second cell column, and are coupled to a second pair of bitlines. The memory cells of the third column are arranged in the third cell column, and are coupled to a third pair of bitlines. The memory cells of the fourth column are arranged in the fourth cell column, and are coupled to a fourth pair of bitlines. The 4-to-1 multiplexer circuit is configured to select one pair of bitlines from among the first pair of bitlines, the second pair of bitlines, the third pair of bitlines and the fourth pair of bitlines, and couple the selected bitline pair to a pair of output nodes. The sense amplifier is configured to sense a data signal on the output nodes, and has a first active area and a second active area separated from each other. Each of the first active area and the second active area is formed in the substrate and coupled to the output nodes. The first active area is formed across a boundary between the first cell column and the second cell column, and the second active area is formed across a boundary between the third cell column and the fourth cell column.

With the use of the proposed sense amplifier layout design, a layout structure of a sense amplifier can be customized to its application environment. In memory applications using 1-to-1 multiplexer circuits, the layout structure of the sense amplifier can have relatively short interconnects and wide transistor widths, thus improving sense amplifier performance. In memory applications using 4-to-1 multiplexer circuits, the layout structure of the sense amplifier can mitigate the impact of layout-dependent effects on device performance, have improved noise immunity, and meet the requirement for high speed operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an exemplary memory device in accordance with some embodiments of the present disclosure.

FIG. 2A to FIG. 2E illustrate exemplary placements of active areas of the sense amplifier circuit shown in FIG. 1 in accordance with some embodiments of the present disclosure.

FIG. 3 illustrates a floorplan of the sense amplifiers shown in FIG. 1 in accordance with some embodiments of the present disclosure.

FIG. 4 illustrates a schematic of at least a portion of each sense amplifier shown in FIG. 3 in accordance with some embodiments of the present disclosure.

FIG. 5 illustrates a layout of at least a portion of each sense amplifier shown in FIG. 3 in accordance with some embodiments of the present disclosure.

FIG. 6 illustrates a floorplan of the sense amplifier shown in FIG. 1 in accordance with some embodiments of the present disclosure.

FIG. 7 illustrates a schematic of at least a portion of the sense amplifier shown in FIG. 6 in accordance with some embodiments of the present disclosure.

FIG. 8 illustrates a layout of at least a portion of each sense amplifier shown in FIG. 6 in accordance with some embodiments of the present disclosure.

FIG. 9 is a flow chart of an exemplary method for forming sense amplifiers of a memory device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

For the transfer of data stored in a memory cell to a sense amplifier, a bitline selection circuit is adopted for selecting a pair of bitlines that are coupled to the memory cell and establishing electrical connection between the selected bitline pair and the sense amplifier. With the use of the bitline selection circuit, one or more columns of memory cells can share the sense amplifier. Memory compilers can generate bitline selection circuits of different types and configurations based on memory applications. For example, a GPU (graphics processing unit) module would need a frame buffer with a wide input/output (I/O) bus. The frame buffer may include a bitline selection circuit implemented using 1-to-1 multiplexer circuits. Each 1-to-1 multiplexer circuit can selectively couple a bitline pair to a sense amplifier. A column of memory cells coupled to the bitline pair can share the sense amplifier. As another example, a CPU (central processing unit) module would need a cache memory with a deep word depth. The cache memory may include a bitline selection circuit implemented using 4-to-1 multiplexer circuits. Each 4-to-1 multiplexer circuit can couple one of four bitline pairs to a sense amplifier. Four columns of memory cells, respectively coupled to the four bitline pairs, can share the sense amplifier.

In general, the sense amplifier layout design for 1-to-1 multiplexer circuits places each sense amplifier within a cell column, in which a column of memory cells is arranged. However, each sense amplifier would have a long and narrow layout area, resulting in larger coupling capacitance on interconnects and increased loads on the sense amplifier during read operations. Such layout design further makes it difficult to reduce circuit areas. In the sense amplifier layout design for 4-to-1 multiplexer circuits, a sense amplifier would be placed within four cell columns, in which four columns of memory cells are arranged respectively. However, it is difficult to realize symmetric placements of transistors and interconnects, thus degrading sensing accuracy.

The present disclosure describes exemplary memory devices, each of which adopts a sense amplifier layout structure capable of reducing asymmetry in layout design and mitigating interference caused by coupling capacitance. The sense amplifier layout structure is applicable to planar semiconductor devices as well as non-planar semiconductor devices such as fin field-effect transistors (FinFETs). The present disclosure further describes exemplary methods for forming sense amplifiers of memory devices. The exemplary methods can provide a suitable sense amplifier layout design according to the type of a bitline selection circuit that is coupled to the sense amplifiers. The exemplary methods can reduce uncertainty in determination of layout structures, and facilitate effective circuit design. Further description is provided below.

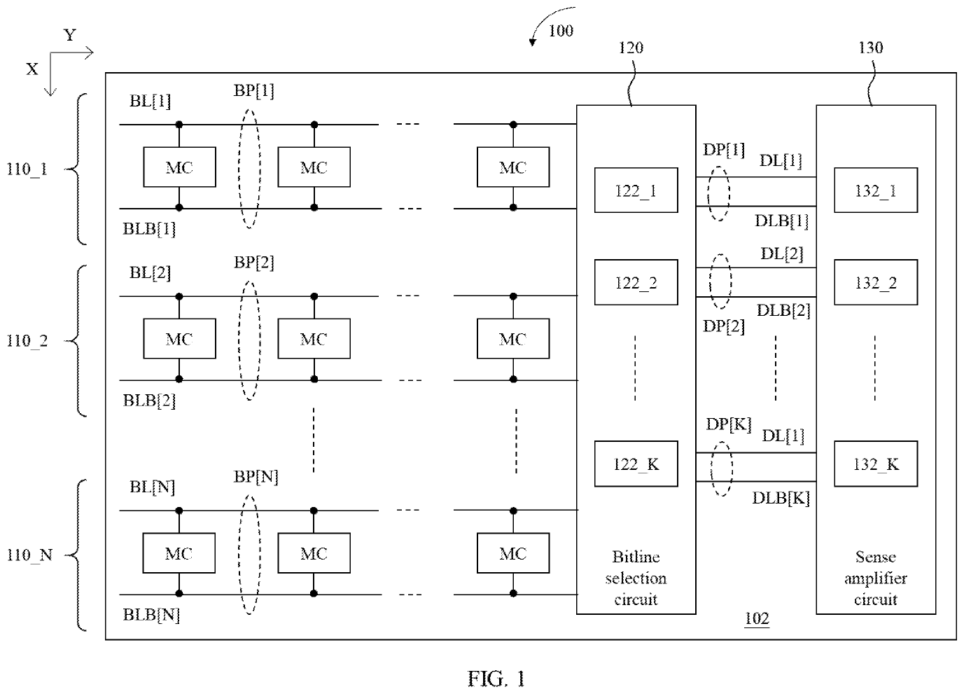

FIG. 1 is a diagram illustrating an exemplary memory device in accordance with some embodiments of the present disclosure. The memory device 100 includes, but is not limited to, columns of memory cells 110_1-110_N, a bitline selection circuit 120, and a sense amplifier circuit 130. N is an integer greater than one. In the present embodiment, each column of memory cells is arranged along a column direction Y and coupled to a pair of bitlines BP[i], where i=1, . . . , N. The bitline pair BP[i] includes complementary bitlines BL[i] and BLB[i]. For example, the column of memory cells 110_1 includes memory cells MC, which share the bitlines BL[1] and BLB[1].

The bitline selection circuit 120 is configured to select one or more pairs of bitlines, and connect each selected pair of bitlines to a corresponding pair of data lines. In the present embodiment, the bitline selection circuit 120 includes a plurality of bitline selectors 122_1-122_K, where K is an integer greater than one. Each bitline selector is configured to couple a selected pair of bitlines to one of pairs of data lines DP[1]-DP[K].

The number of bitline selectors may be equal to the number of bitline pair, i.e. K=N. Each bitline selector can be implemented using a 1-to-1 multiplexer circuit, and configured to selectively couple a pair of bitlines BP[i] to a pair of data lines DP[i], where i=1, . . . , N. The data line pair DP[i] includes complementary data lines DL[i] and DLB[i]. Alternatively, the number of bitline selectors may be equal to one quarter of the number of bitline pairs, i.e. K=N/4. Each bitline selector can be implemented using a 4-to-1 multiplexer circuit. Each bitline selector can be configured to select one pair of bitlines from among four pairs of bitlines, and couple the selected pair of bitlines to one pair of data lines.

The sense amplifier circuit 130, coupled to the data line pairs DP[1]-DP[K], is configured to sense and amplify a data signal on each pair of data lines. The circuit design or layout structure of the sense amplifier circuit 130 is determined according to the type of each bitline selector incorporated in the bitline selection circuit 120. In the example of FIG. 1, the sense amplifier circuit 130 includes a plurality of sense amplifiers 132_1-132_K. Each sense amplifier includes one or more active areas on which transistors are formed. The active areas can be arranged/placed according to the type of the bitline selector coupled to the sense amplifier.

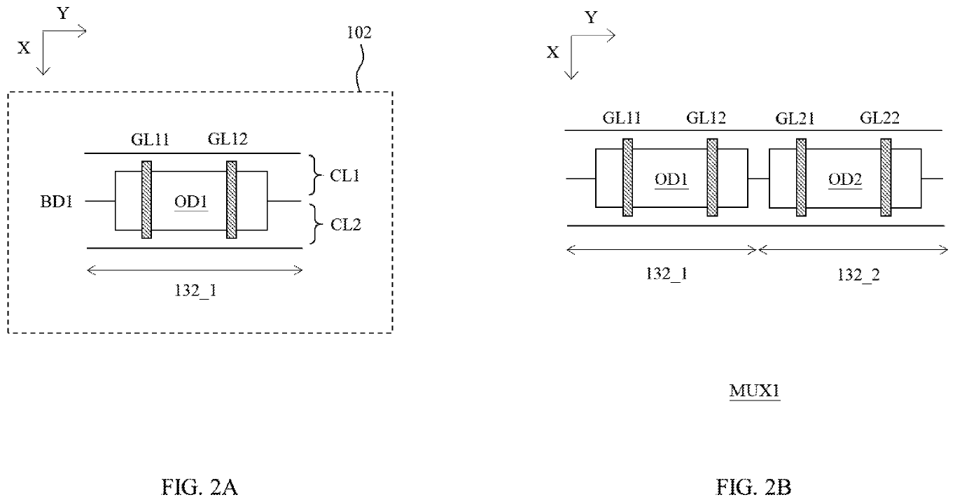

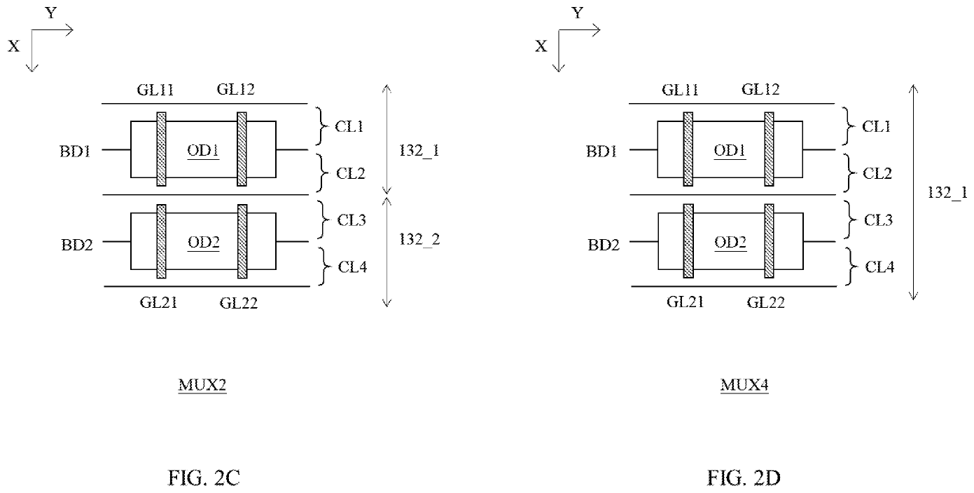

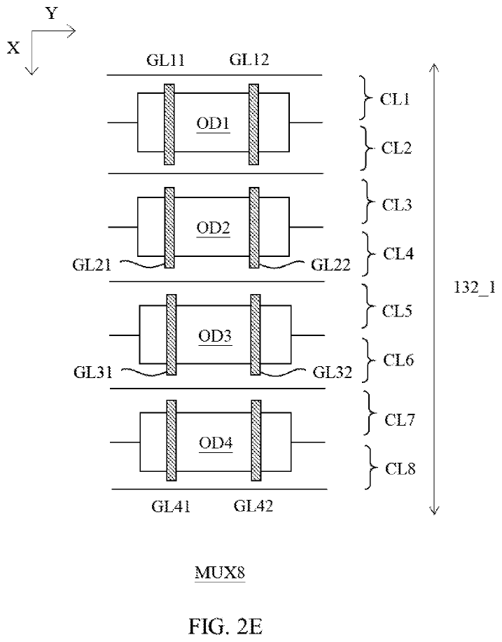

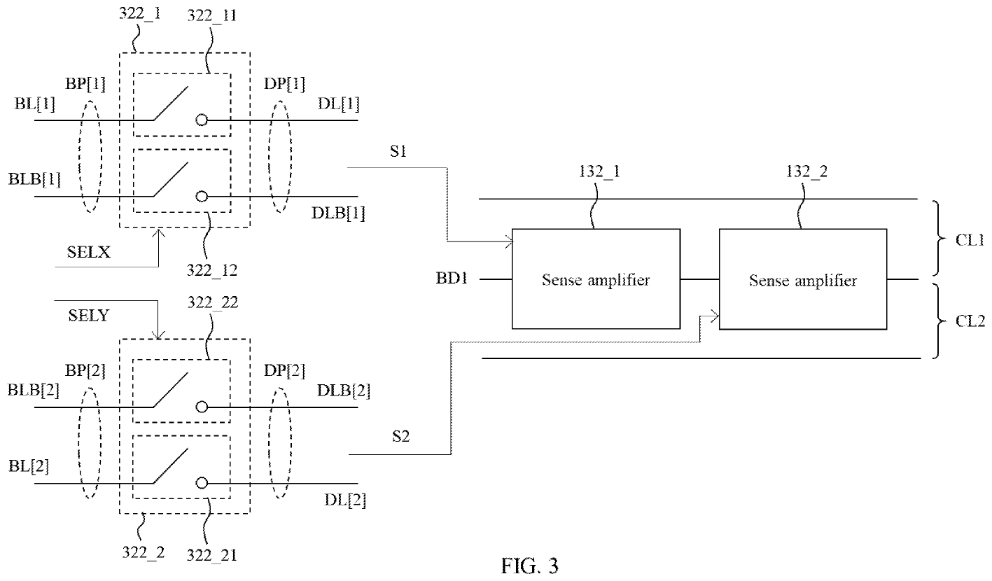

FIG. 2A to FIG. 2E illustrate exemplary placements of active areas of the sense amplifier circuit 130 shown in FIG. 1 in accordance with some embodiments of the present disclosure. For the sake of brevity, the placements shown in FIG. 2A to FIG. 2E are described with the sense amplifiers 132_1 and 132_2 shown in FIG. 1. Those skilled in the art should appreciate that other sense amplifiers shown in FIG. 1 can be implemented based on the placements shown in FIG. 2A to FIG. 2E.

Referring firstly to FIG. 2A and also to FIG. 1, the sense amplifier 132_1 is placed in an oxide definition region that defines an active area OD1 of the substrate 102. The substrate 102 includes adjacent cell columns CL1 and CL2. The column of memory cells 110_1 may be arranged in the cell column CL1 along the column direction Y, and the column of memory cells 110_2 may be arranged in the cell column CL2 along the column direction Y. The active area OD1 extends across a boundary BD1 between the cell columns CL1 and CL2. One or more transistors of the sense amplifier 132_1 can be formed on the active area OD1. In the example of FIG. 2A, gate structures GL11 and GL12, such as polysilicon gate lines, are disposed on the active area OD1 to form transistors. Each gate structure can extend in a row direction X substantially perpendicular to the column direction Y.

Referring to FIG. 2B and also to FIG. 1, the sense amplifier circuit 130 can be implemented using the layout structure MUX1 when each bitline selector is implemented as a 1-to-1 multiplexer circuit. In the layout structure MUX1, two separate active areas OD1 and OD2 both extend across the cell columns CL1-CL2 and are placed or formed along the column direction Y. The active areas OD1 and OD2 may have substantially identical dimensions. The gate structures GL11 and GL12 are disposed on the active area OD1 to form transistors of the sense amplifier 132_1. Similarly, gate structures GL21 and GL22, such as polysilicon gate lines, are disposed on the active area OD2 to form transistors of the sense amplifier 132_2. Note that, in the layout structure MUX1, the sense amplifier 132_1 can be dedicated to sensing a data signal on the bitline pair BP[1] through the bitline selector 122_1, i.e. a 1-to-1 multiplexer circuit. The sense amplifier 132_2 can be dedicated to sensing a data signal on the bitline pair BP[2] through the bitline selector 122_2, which is a 1-to-1 multiplexer circuit.

Referring to FIG. 2C and also to FIG. 1, the sense amplifier circuit 130 can be implemented using the layout structure MUX2 when each bitline selector is implemented as a 2-to-1 multiplexer circuit. In the layout structure MUX2, two separate active areas OD1 and OD2 are formed along the row direction X. The active areas OD1 and OD2 may have substantially identical dimensions. In other words, the active area OD2 extends across a boundary BD2 between adjacent cell columns CL3 and CL4 of the substrate 102. The column of memory cells 110_3 may be arranged in the cell column CL3, and the column of memory cells 110_4 may be arranged in the cell column CL4. Moreover, the gate structures GL11 and GL12 are disposed on the active area OD1 to form transistors of the sense amplifier 132_1. The gate structures GL21 and GL22 are disposed on the active area OD2 to form transistors of the sense amplifier 132_2. Note that, in the layout structure MUX2, the sense amplifier 132_1 can be configured to sense a data signal provided from the bitline selector 122_1, i.e. a 2-to-1 multiplexer circuit operable to select one pair of bitlines from the bitline pairs BP[1] and BP[2]. The sense amplifier 132_2 can be configured to sense a data signal provided from the bitline selector 122_2, i.e. a 2-to-1 multiplexer circuit operable to select one pair of bitlines from the bitline pairs BP[3] and BP[4].

Referring to FIG. 2D and also to FIG. 1, the sense amplifier circuit 130 can be implemented using the layout structure MUX4 when each bitline selector is implemented as a 4-to-1 multiplexer circuit. In the layout structure MUX4, the sense amplifier 132_1 can be formed on the cell columns CL1-CL4 arranged in parallel, and configured to sense a data signal provided from the bitline selector 122_1. The bitline selector 122_1 is implemented as a 4-to-1 multiplexer circuit that is operable to select one pair of bitlines from among four pairs of bitlines BP[1]-BP[4]. The sense amplifier 132_1 includes two separate active areas OD1 and OD2 formed along the row direction X. The active area OD1 is formed across the boundary BD1 between the cell columns CL1 and CL2. The active area OD2 is formed across the boundary BD2 between the cell columns CL3 and CL4. The gate structures GL11 and GL12 are disposed on the active area OD1, and the gate structures GL21 and GL22 are disposed on the active area OD2. In some embodiments, the gate structures GL11 and GL21 may be replaced with one gate structure extending across both of the active areas OD1 and OD2 along the row direction X.

Similarly, the gate structures GL12 and GL22 may be replaced with one gate structure extending across both of the active areas OD1 and OD2 along the row direction X.

Referring to FIG. 2E and also to FIG. 1, the sense amplifier circuit 130 can be implemented using the layout structure MUX8 when each bitline selector is implemented as an 8-to-1 multiplexer circuit. In the layout structure MUX8, the sense amplifier 132_1 can be formed on the cell columns CL1-CL8 arranged in parallel, and configured to sense a data signal provided from the bitline selector 122_1. The bitline selector 122_1 is implemented as an 8-to-1 multiplexer circuit that is operable to select one pair of bitlines from among eight pairs of bitlines BP[1]-BP[8]. The sense amplifier 1321 includes four separate active areas OD1-OD4 formed along the row direction X. The active areas OD1-OD4 may have substantially identical dimensions. In other words, each active area is formed across a boundary between two cell columns. The gate structures GL11 and GL12 are disposed on the active area OD1, the gate structures GL21 and GL22 are disposed on the active area OD2, the gate structures GL31 and GL32 are disposed on the active area OD3, and the gate structures GL41 and GL42 are disposed on the active area OD4. In some embodiments, the gate structures GL11, GL21, GL31 and GL41 may be replaced with one gate structure extending across each active area along the row direction X. Similarly, the gate structures GL12, GL22, GL32 and GL42 may be replaced with one gate structure extending across each active area along the row direction X.

As active areas of sense amplifiers can be arranged along the column direction or the row direction according to the type of the bitline selector, the proposed sense amplifier layout design can improve sense amplifier performance in various memory applications. To facilitate understanding of the present disclosure, some embodiments of the layout structures MUX1 and MUX4 shown in FIG. 2 are given below for further description of the proposed sense amplifier layout design. However, this is provided for illustrative purposes, and is not intended to limit the scope of the present disclosure. As long as a sense amplifier circuit includes active areas formed along a direction which is determined according to the type of the bitline selector, and each active area is formed across a boundary between two adjacent cell columns, associated modifications and alternatives are contemplated as falling within the scope of the present disclosure.

FIG. 3 illustrates a floorplan of the sense amplifiers 132_1 and 132_2 shown in FIG. 1 in accordance with some embodiments of the present disclosure. The sense amplifiers 132_1 and 132_2 can be implemented using the layout structure MUX1 shown in FIG. 2B. In the present embodiment, the sense amplifiers 132_1 and 132_2 are both formed across the boundary BD1 between the cell columns CL1 and CL2.

The sense amplifier 132_1 is configured to receive a data signal S1 on a pair of data lines DP[1] from a 1-to-1 multiplexer circuit 322_1, which can serve as an embodiment of the bitline selector 122_1 shown in FIG. 1. The 1-to-1 multiplexer circuit 322_1 is configured to couple the bitline pair BP[1] to the data line pair DP[1]. For example, the 1-to-1 multiplexer circuit 322_1 may include two switches 322_11 and 322_12, i.e. two 1-to-1 multiplexers. The switch 322_11 is selectively coupled between the bitline BL[1] and the data line DL[1]. The switch 322_12 is selectively coupled between the bitline BLB[1] and the data line DLB[1]. Each of the switches 322_11 and 322_12 can be controlled by the same control signal SELX.

The sense amplifier 132_2 is configured to receive a data signal S2 on a pair of data lines DP[2] from a 1-to-1 multiplexer circuit 322_2, which can serve as an embodiment of the bitline selector 122_2 shown in FIG. 1. The 1-to-1 multiplexer circuit 322_2 is configured to couple the bitline pair BP[2] to the data line pair DP[2]. For example, the 1-to-1 multiplexer circuit 322_2 may include two switches 322_21 and 322_22. The switch 322_21 is selectively coupled between the bitline BL[2] and the data line DL[2]. The switch 322_12 is selectively coupled between the bitline BLB[2] and the data line DLB[2]. Each of the switches 322_11 and 322_12 can be controlled by the same control signal SELY.

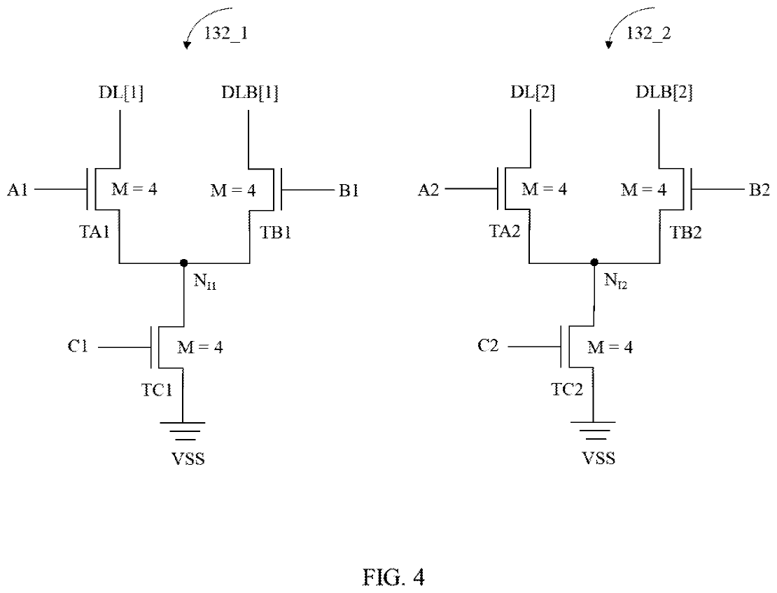

FIG. 4 illustrates a schematic of at least a portion of each sense amplifier shown in FIG. 3 in accordance with some embodiments of the present disclosure. The sense amplifier 132_1 may include transistors TA1, TB1 and TC1, which constitute a major portion of the sense amplifier 132_1. In the present embodiment, a transistor symbol with a multiplier factor M represents that M transistors connected in parallel would be formed. In other words, the sense amplifier 132_1 includes four transistors TA1 connected in parallel, four transistors TB1 connected in parallel, and four transistors TC1 connected in parallel.

In the example of FIG. 4, the gate region, the first source/drain region and the second source/drain region of each transistor TA1 are coupled to the conductive line A1, the data line DL[1] and the circuit node N₁₁ respectively. The gate region, the first source/drain region and the second source/drain region of each transistor TB1 are coupled to the conductive line B1, the data line DLB[1] and the circuit node N₁₁, respectively. The gate region, the first source/drain region and the second source/drain region of each transistor TC1 are coupled to the conductive line C1, the circuit node N₁₁ and the reference voltage VSS, respectively. The reference voltage VSS may be the ground voltage.

The circuit structure of the sense amplifier 132_2 is identical or substantially identical to that of the sense amplifier 132_1. In other words, the sense amplifier 132_2 may include four transistors TA2 connected in parallel, four transistors TB2 connected in parallel, and four transistors TC2 connected in parallel. The gate region, the first source/drain region and the second source/drain region of each transistor TA2 are coupled to the conductive line A2, the data line DL[2] and the circuit node N₁₂, respectively. The gate region, the first source/drain region and the second source/drain region of each transistor TB2 are coupled to the conductive line B2, the data line DLB[2] and the circuit node N₁₂, respectively. The gate region, the first source/drain region and the second source/drain region of each transistor TC2 are coupled to the conductive line C2, the circuit node N₁₂ and the reference voltage VSS.

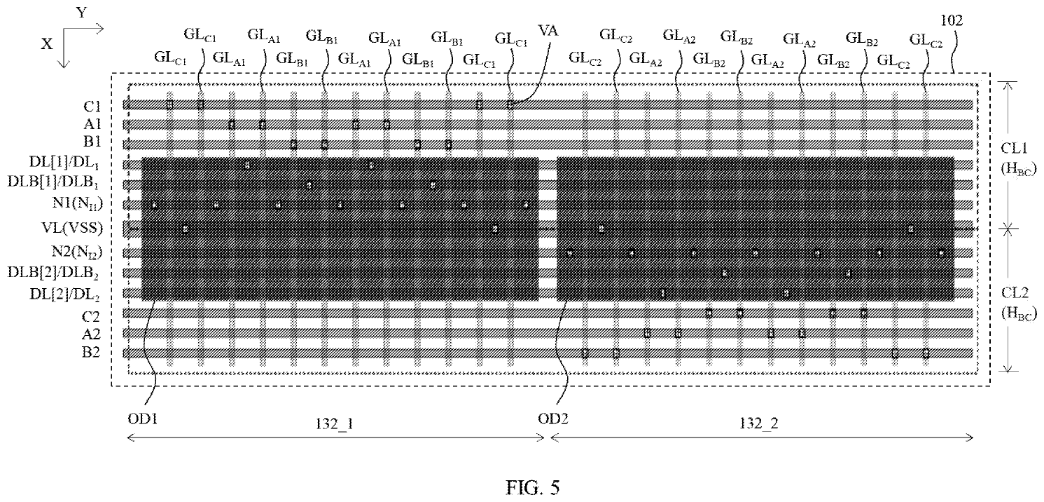

FIG. 5 illustrates a layout of at least a portion of each sense amplifier shown in FIG. 3 in accordance with some embodiments of the present disclosure. The layout shown in FIG. 5 can serve as an embodiment of the physical connections between circuit elements shown in FIG. 4. Each of the transistors TA1, TA2, TB1, TB2, TC1 and TC2 is laid out in multiple components, in which the components of the transistors are connected together to respectively form the sense amplifiers 132_1 and 132_2 through metal contacts and vias between different metal layers of the interconnect structure of the memory device. Referring to FIG. 5 and also to FIG. 4, the gate structures GL_{A1}, GL_{B1} and GL_{C1} are arranged in parallel across the active area OD1 along the row direction X to form the transistors TA1, TB1 and TC1. The gate structures GL_{A1}, GL_{B1} and GL_{C1} are used to implement gate regions of the transistors TA1, TB1 and TC1, respectively. Similarly, the gate structures GL_{A2}, GL_{B2} and GL_{C2} are arranged in parallel across the active area OD2 along the row direction X to form the transistors TA2, TB2 and TC2. The gate structures GL_{A2}, GL_{B2} and GL_{C2} are used to implement gate regions of the transistors TA2, TB2 and TC2, respectively.

Each gate structure may be arranged at the same or substantially the same level. In other words, each gate structure may be arranged in substantially the same plane above the substrate 102, or formed in the same layer. For example, each gate structure is formed by patterning the same polysilicon layer. In the present embodiment, from the top view of the substrate 102, an upper edge and a lower edge of each active area are located within the cell column CL1 and the cell column CL2, respectively. Thus, each transistor can have a width equal to or greater than the bitcell height H_{BC}, i.e. the column width of each cell column.

As shown in FIG. 5, each of the conductive lines A1, B1, C1, N1, VL, A2, B2, C2 and N2 extends along the column direction Y. The data lines DL[1] and DLB[1], arranged in the cell column CL1, may extend across the active areas OD1 and OD2 along the column direction Y. The data lines DL[2] and DLB[2] are arranged in the cell column CL2. The data lines DL[2] and DLB[2] may extend across the active areas OD2 and OD2 along the column direction Y. Each conductive line and each data line can be formed by patterning the same metal layer.

An interconnect structure including a plurality of contacts VA is formed to provide electrical connection between each gate structure and an associated conductive line. For example, the gate structures GL_{A1} are electrically connected to the conductive line A1 through the contacts VA formed thereon. The gate structures GL_{B1} are electrically connected to the conductive line B1 through the contacts VA formed thereon. The gate structures GL_{C1} are electrically connected to the conductive line C1 through the contacts VA formed thereon. Similarly, the gate structures GL_{A2}/GL_{B2}/GL_{C2} are electrically connected to the conductive line A2/B2/C2 through the contacts VA formed thereon.

The interconnect structure further includes a plurality of contacts VA to provide electrical connection between a source/drain region and an associated conductive line. For example, the conductive line N1 is electrically connected to the second source/drain region of each transistor TA1, the second source/drain region of each transistor TB1, and the first source/drain region of each transistor TC1 through associated contacts VA, thereby forming the circuit node N₁₁. Similarly, the conductive line N2 is electrically connected to the second source/drain region of each transistor TA2, the second source/drain region of each transistor TB2, and the first source/drain region of each transistor TC2 through associated contacts VA, thereby forming the circuit node N₁₂. Moreover, the conductive line VL is arranged to couple the reference voltage VSS to the second source/drain region of each transistor TC1/TC2.

According to one embodiment of the present disclosure, the data lines DL[1], DLB[1], DL[2] and DLB[2] are conductive lines placed in one or more metal layers. The data lines DL[1] and DLB[1], i.e. a pair of conductive lines, are constructed using the first pair of metal lines DL₁ and DLB₁ which are coupled to the sense amplifier 132_1 via a group of contacts VA within the active area OD1; the sense amplifier 132_1 is placed in a layout portion including the active area OD1. Likewise, the data lines DL[2] and DLB[2] are constructed using the second pair of metal lines DL₂ and DLB₂ which are coupled to the sense amplifier 132_2 via another group of contacts VA within the active area OD2; the sense amplifier 132_2 is placed in another layout portion including the active area OD2. Thus, the sense amplifier 132_1 can be dedicated to sensing a differential signal on the data lines DL[1] and DLB[1]. The sense amplifier 132_2 can be dedicated to sensing a differential signal on the data lines DL[2] and DLB[2].

Note that the gate structures GL_{A1}, GL_{B1} and GL_{C1} can be arranged in an interleaved manner to mitigate the effects of process variations. For example, the gate structures GL_{A1} can be interleaved with the gate structures GL_{B1}. As another example, at least one gate structure GL_{A1} and at least one gate structure GL_{B1} can be placed between two gate structures GL_{C1}. In the embodiment of the planar view shown in FIG. 5, two gate structures GL_{A1} and two gate structures GL_{B1} are alternately disposed between the gate structures GL_{C1} that are on the opposite outer sides of the region of the sense amplifier 132_1.

Compared with a sense amplifier layout structure having an active area placed within a single cell column, the proposed sense amplifier layout structure can have relatively short interconnects and wide transistor widths, thus improving sense amplifier performance in memory applications using 1-to-1 multiplexer circuits. Furthermore, the proposed sense amplifier layout structure can arrange a group of transistors connected in parallel and another group of transistors connected in parallel in an interleaved manner to mitigate the effects of process variations.

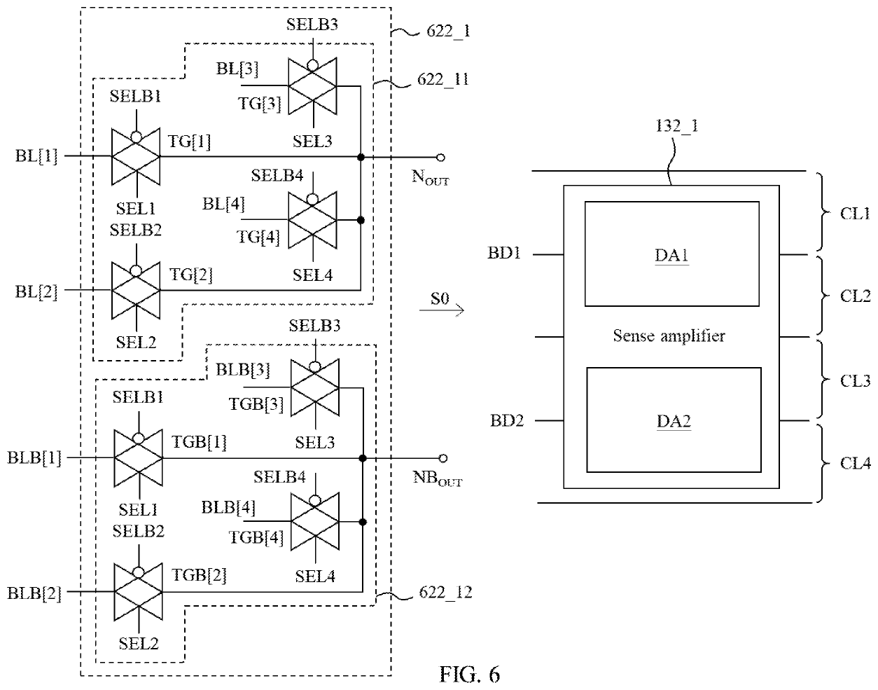

FIG. 6 illustrates a floorplan of the sense amplifier 132_1 shown in FIG. 1 in accordance with some embodiments of the present disclosure. The sense amplifier 132_1 can be implemented using the layout structure MUX4 shown in FIG. 2D. In the present embodiment, the sense amplifier 132_1 is formed in the cell columns CL1-CL4, and includes two active areas OD1 and OD2 spaced apart from each other. The components of a sense amplifier can be placed on the active areas OD1 and OD2. The active area OD1 is formed across the boundary BD1 between the cell columns CL1 and CL2. The active area OD2 is formed across the boundary BD2 between the cell columns CL3 and CL4.

The sense amplifier 132_1 is configured to sense a data signal S0 on a pair of output nodes N_{OUT} and NB_{OUT} of a 4-to-1 multiplexer circuit 622_1, which can serve as an embodiment of the bitline selector 122_1 shown in FIG. 1. The 4-to-1 multiplexer circuit 622_1 is configured to select one pair of bitlines from among four pairs of bitlines, and couple the selected bitline pair to the output nodes N_{OUT} and NB_{OUT}. For example, the 4-to-1 multiplexer circuit 622_1 may include two 4-to-1 multiplexers 622_11 and 622_12. The 4-to-1 multiplexer 622_11 is configured to select one of four bitlines BL[1]-BL[4], and couple the selected one to the output node N_{OUT}. The 4-to-1 multiplexer 622_12 is configured to select one of four bitlines BLB[1]-BLB[4], and couple the selected one to the output node NB_{OUT}.

In the present embodiment, the 4-to-1 multiplexer 622_11 can be implemented to include four transmission gates TG[1]-TG[4]. The 4-to-1 multiplexer 622_12 can be implemented to include four transmission gates TGB[1]-TGB[4]. Each transmission gate is controlled by a pair of control signals. For example, the transmission gate TG[1]/TGB[1] is controlled by a pair of control signals SEL1 and SELB1. The transmission gate TG[2]/TGB[2] is controlled by a pair of control signals SEL2 and SELB2. The transmission gate TG[3]/TGB[3] is controlled by a pair of control signals SEL3 and SELB3. The transmission gate TG[4]/TGB[4] is controlled by a pair of control signals SEL4 and SELB4.

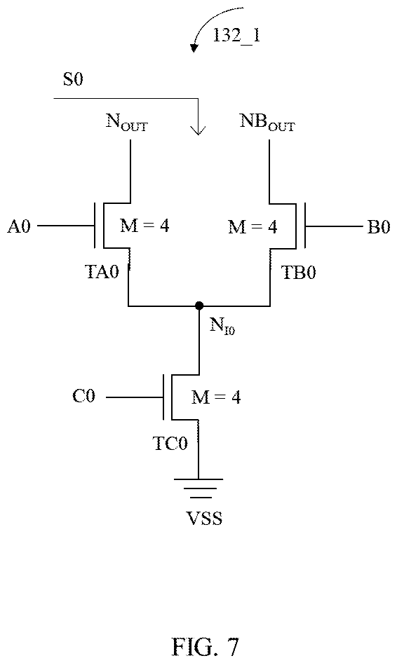

FIG. 7 illustrates a schematic of at least a portion of the sense amplifier 132_1 shown in FIG. 6 in accordance with some embodiments of the present disclosure. The sense amplifier 132_1 may include transistors TA0, TB0 and TC0, which constitute a major portion of the sense amplifier 132_1. In the present embodiment, the multiplier factor M associated with each transistor symbol is 4. In other words, the sense amplifier 132_1 includes four transistors TA0 connected in parallel, four transistors TB0 connected in parallel, and four transistors TC0 connected in parallel.

In the example of FIG. 7, the gate region, the first source/drain region and the second source/drain region of each transistor TA0 are coupled to the conductive line A0, the output node N_{OUT} and the circuit node N₁₀, respectively. The gate region, the first source/drain region and the second source/drain region of each transistor TB0 are coupled to the conductive line B0, the output node NB_{OUT} and the circuit node N₁₀, respectively. The gate region, the first source/drain region and the second source/drain region of each transistor TC0 are coupled to the conductive line C0, the circuit node N₁₀ and the reference voltage VSS, respectively.

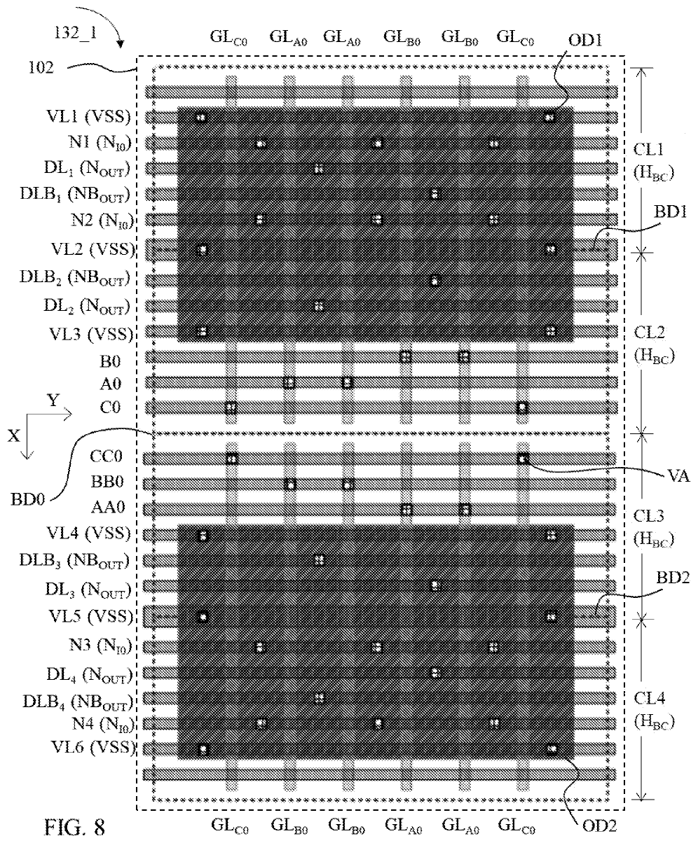

FIG. 8 illustrates a layout of at least a portion of each sense amplifier 132_1 shown in FIG. 6 in accordance with some embodiments of the present disclosure. The layout shown in FIG. 8 can serve as an embodiment of the physical connections between circuit elements shown in FIG. 7. Each of the transistors TA0, TB0 and TC0 is laid out in multiple components, in which the components of the transistors are connected together to form the sense amplifiers 132_1 through metal contacts and vias between different metal layers of the interconnect structure of the memory device. Referring to FIG. 8 and also to FIG. 7, the gate structures GL_{A0}, GL_{B0} and GL_{C0} are arranged in parallel across the active area OD1/OD2 along the row direction X to form the transistors TA0, TB0 and TC0. At least one transistor TA0, at least one transistor TB0, and at least one transistor TC0 can be formed on the active area OD1. In addition, at least one transistor TA0, at least one transistor TB0, and at least one transistor TC0 can be formed on the active area OD2. The gate structures GL_{A0}, GL_{B0} and GL_{C0} are used to implement gate regions of the transistors TA0, TB0 and TC0, respectively.

The data signal S0 of the 4-to-1 multiplexer circuit 622_1 shown in FIG. 6 is fed to the sense amplifier 132_1 at the output nodes N_{OUT} and NB_{OUT}. The sense amplifier 132_1 is placed in a layout portion including two separate active areas and receives the data signal S0 through a pair of conductive lines, each of which has four segments of metal lines DLᵢ/DLBᵢ, where i=1, 2, 3, 4. As illustrated in FIG. 8, the first pair of metal lines DL₁ and DLB₁ are formed in the cell column CL1 while the second pair of metal lines DL₂ and DLB₂ are formed in the cell column CL2. Similarly, the third pair of metal lines DL₃ and DLB₃ are formed in the cell column CL3 while the fourth pair of metal lines DL₄ and DLB are formed in the cell column CL4. The metal lines DL₁-DL₄ are coupled via a group of metal contacts VA within the active areas OD1 and OD2. Also, the metal lines DLB₁-DLB₄ are coupled via another group of metal contacts VA within the active areas OD1 and OD2. In this way, the conductive line pair is constructed to convey the data signal S0.

In the present embodiment, a portion of the gate structures GL_{A0} can extend across on the active area OD1 along a direction substantially perpendicular to the boundary BD1. Another portion of the gate structures GL_{A0} can extend across on the active area OD2 along a direction substantially perpendicular to the boundary BD2. The portion of the gate structures GL_{A0} and the another portion of the gate structures GL_{A0} can be are arranged mirror-symmetrically with respect to a boundary BD0 between the cell column CL2 and the cell column CL3. The gate structure GL_{A0} formed on the active area OD1 is separated from the gate structure GL_{A0} formed on the active area OD2. For example, two of the gate structures GL_{A0} are arranged in parallel across the active area OD1, and the other two of the gate structures GL_{A0} are arranged in parallel across the active area OD2. The gate structures GL_{A0} formed on the active area OD1 and the gate structures GL_{A0} formed on the active area OD2 are arranged mirror-symmetrically with respect to the boundary BD0.

Similarly, the gate structure GL_{B0} formed on the active area OD1 is separated from the gate structure GL_{B0} formed on the active area OD2. Two of the gate structures GL_{B0} are arranged in parallel across the active area OD1, and the other two of the gate structures GL_{B0} are arranged in parallel across the active area OD2. The gate structure GL_{C0} formed on the active area OD1 is separated from the gate structure GL_{C0} formed on the active area OD2. Two of the gate structures GL_{C0} are arranged in parallel across the active area OD1, and the other two of the gate structures GL_{C0} are arranged in parallel across the active area OD2. With respect to each active area, each gate structure GL_{A0} and each gate structure GL_{B0} can be placed between two gate structures GL_{C0} that are on the opposite outer sides as illustrated in FIG. 8.

Note that, from the top view of the substrate 102, an upper edge and a lower edge of the active area OD1 are located within the cell column CL1 and the cell column CL2, respectively. An upper edge and a lower edge of the active area OD2 are located within the cell column CL3 and the cell column CL4, respectively. Thus, each transistor can have a width equal to or greater than the bitcell height H_{BC}, i.e. the column width of each cell column.

Signal lines extending along the column direction Y include conductive lines A0, B0, C0, AA0, BB0, CC0, N1-N4, and VL1-VL6. The conductive lines A0 and AA0 are electrically connected, the conductive lines B0 and BB0 are electrically connected, and the conductive lines C0 and CC0 are electrically connected. The conductive lines N1-N4 are electrically connected. Each of the conductive lines VL1-VL6 is coupled to the reference voltage VSS. In addition, each of the metal lines DL₁, DLB₁, DL₂ and DLB₂ extends across the active area OD1 along the column direction Y. Each of the metal lines DL₃, DLB₃, DL₄ and DLB₄ extends across the active area OD2 along the column direction Y.

An interconnect structure including a plurality of contacts VA is formed to provide electrical connection between each gate structure and an associated conductive line. For example, the gate structures GL_{A0} formed on the active area OD1 are electrically connected to the conductive line A0 through associated contacts VA. The gate structures GL_{A0} formed on the active area OD2 are electrically connected to the conductive line AA0 through associated contacts VA. Similarly, the gate structures GL_{B0} formed on the active area OD1/OD2 are electrically connected to the conductive line B0/BB0 through the contacts VA. The gate structures GL_{C0} formed on the active area OD1/OD2 are electrically connected to the conductive line C0/CC0 through associated contacts VA.

The interconnect structure further includes a plurality of contacts VA to provide electrical connection between a source/drain region and an associated conductive line. For example, each of the conductive lines N1-N4 is electrically connected to associated source/drain regions to form the circuit node N₁₀. Each of the conductive lines VL1-VL6 is arranged to couple the reference voltage VSS to the second source/drain region of transistor TC0 through associated contacts VA. Moreover, the interconnect structure includes a plurality of contacts VA arranged to electrically connect data lines to a corresponding active area.

Note that signal lines which are electrically connected to each other can be arranged symmetrically with respect to the boundary BD0. For example, the conductive lines VL1-VL6 are arranged symmetrically with respect to the boundary BD0. Also, the arrangement of gate structures shown in FIG. 8 is symmetrical with respect to the boundary BD0. Thus, the transistors TA0, TB0 and TC0 can be arranged in a symmetric manner to mitigate the impact of layout-dependent effects on device performance and reliability. In other words, as a differential signal outputted from the 4-to-1 multiplexer circuit 622_1 travels through two active areas OD1 and OD2 illustrated in the embodiment of FIG. 8, in which transistors and conductive lines are formed in a symmetric manner, the sense amplifier 132_1 can have improved noise immunity and meet the requirements for high speed operation.

Compared with a sense amplifier layout structure having a single active area placed within four cell columns, the proposed sense amplifier layout structure can place transistors connected in parallel at separate active areas in a symmetric manner, thereby reducing the effects of parasitic capacitance mismatches and maintaining uniform boundary effects of oxide layers. The proposed sense amplifier layout structure can be applied to various high-speed memory applications.

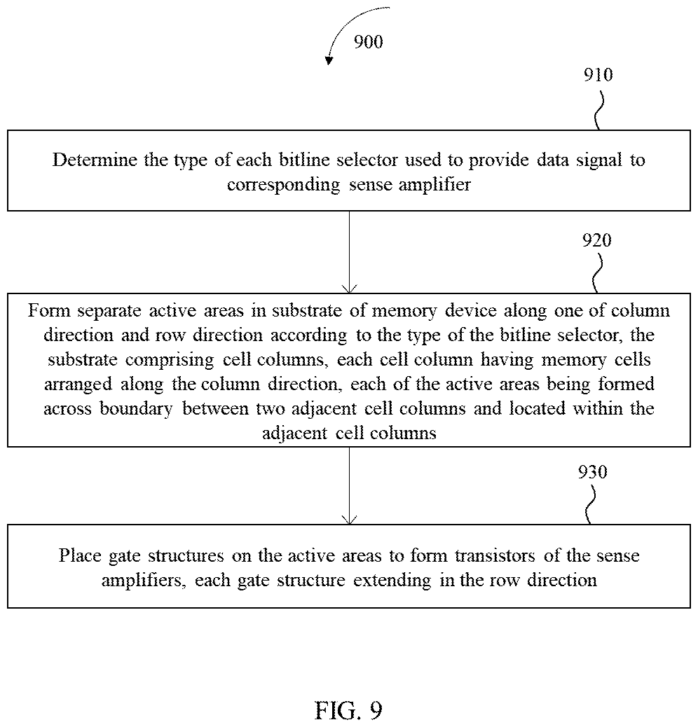

FIG. 9 is a flow chart of an exemplary method for forming sense amplifiers of a memory device in accordance with some embodiments of the present disclosure. For illustrative purposes, the method 900 is described below with reference to the memory device 100 shown in FIG. 1 and the placements shown in FIG. 2. Note that the method 900 can be employed for forming sensing amplifiers provided for various types of bitline selectors, e.g. an X-to-1 multiplexer circuit where X is a positive integer, without departing from the scope of the present disclosure. Additionally, in some embodiments, other operations in the method 900 can be performed.

At operation 910, the type of each bitline selector used to provide a data signal to a corresponding sense amplifier is determined. For example, a memory complier can determine the type of each of the bitline selectors 122_1-122_K.

At operation 920, a plurality of separate active areas are formed in a substrate of the memory device along one of the column direction and the row direction according to the type of the bitline selector. The substrate includes a plurality of cell columns, and each cell column has a plurality of memory cells arranged along the column direction. Each of the active areas is formed across a boundary between two adjacent cell columns and located within the adjacent cell columns. For example, the columns of memory cells 110_1-110_N are arranged in N cell columns (not shown in FIG. 1) of the substrate 102, respectively. A plurality of separate active areas can be formed in the substrate 102 along the column direction Y or the row direction X according to the type of each bitline selector.

In some embodiments, when it is determined that each bitline selector is a 1-to-1 multiplexer circuit, the active areas can be formed along the column direction. For example, when the memory device 100 is employed in a GPU module, each of the bitline selectors 122_1-122_K can be implemented using a 1-to-1 multiplexer circuit. The layout structure of the sense amplifier circuit 130 can be implemented based on the layout structure MUX1 shown in FIG. 2B.

In some embodiments, when it is determined that each bitline selector is an X-to-1 multiplexer circuit, the active areas can be formed along the row direction. X is a multiple of 2. For example, when the memory device 100 is employed in a CPU module, each of the bitline selectors 122_1-122_K can be implemented using a 4-to-1 multiplexer circuit. The layout structure of the sense amplifier circuit 130 can be implemented based on the layout structure MUX4 shown in FIG. 2D.

At operation 930, a plurality of gate structures are placed on the active areas to form transistors of the sense amplifiers. Each gate structure extends in the row direction perpendicular to the column direction. For example, the gate structures GL11 and GL12 can be placed on the active area OD1 shown in FIG. 2D to form a portion of transistors of the sense amplifier 132_1.

In some embodiments, a plurality of gate structures can be arranged on each active area to form first transistors connected in parallel. Moreover, a plurality of gate structures can be arranged on the same active area to form second transistors connected in parallel. The gate structures of the first transistor are interleaved with the gate structures of the second transistors. For example, in the embodiment shown in FIG. 5, the gate structures GL_{A1}, GL_{B1} and GL_{C1} can be arranged in an interleaved manner to mitigate the effects of process variations.

In some embodiments, gate structures of transistors connected in parallel can be arranged on separate active areas in a symmetric manner. For example, in the embodiment shown in FIG. 8, the gate structures GL_{A0}/GL_{B0}/GL_{C0} can be arranged mirror-symmetrically with respect to the boundary BD0, thereby reducing the effects of parasitic capacitance mismatches and maintaining uniform boundary effects of oxide layers.

As those skilled in the art can appreciate the operation of the method 900 after reading the above paragraphs directed to FIG. 1 through FIG. 8, further description is omitted here for brevity.

With the use of the proposed sense amplifier layout design, a layout structure of a sense amplifier can be customized to its application environment. For example, in memory applications using 1-to-1 multiplexer circuits, the layout structure of the sense amplifier can have relatively short interconnects and wide transistor widths, thus improving sense amplifier performance. As another example, in memory applications using 4-to-1 multiplexer circuits, the layout structure of the sense amplifier can mitigate the impact of layout-dependent effects on device performance, have improved noise immunity, and meet the requirement for high speed operation.

The foregoing outlined features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming sense amplifiers of a memory device, comprising:
determining a type of each bitline selector used to provide a data signal to a corresponding sense amplifier;
forming a plurality of separate active areas in a substrate of the memory device along one of a column direction and a row direction according to the type of the bitline selector, wherein the substrate comprises a plurality of cell columns, each of the cell columns has a plurality of memory cells arranged along the column direction, and each of the active areas is formed across a boundary between two adjacent cell columns and located within the adjacent cell columns; and
arranging a plurality of gate structures on the active areas to form transistors of the sense amplifiers, each gate structure extending in the row direction.

2. The method of claim 1, wherein the step of forming the separate active areas comprises:
when the type of a bitline selector determined is a 1-to-1 multiplexer circuit, forming the active areas along the column direction; and
when the type of a bitline selector determined is an X-to-1 multiplexer circuit, forming the active areas along the row direction, wherein X is a multiple of 2.

3. The method of claim 2, wherein the active areas formed along the column direction comprises a first active area and a second active area; each of the first active area and the second active cell area is located within a first cell column and a second cell column adjacent to each other; the method further comprises:
forming a first pair of metal lines in the first cell column, the first pair of metal lines extending across the first active area and the second active area; and
forming a second pair of metal lines in the second cell column, the second pair of metal lines extending across the first active area and the second active area;
wherein the first pair of metal lines are coupled to a first sense amplifier via a first group of contacts within the first active area and adapted to transmit a data signal of a first 1-to-1 multiplexer to the first sense amplifier placed in a layout portion including the first active area;
wherein the second pair of metal lines are coupled to a second sense amplifier via a second group of contacts within the second active area and adapted to transmit a data signal of a second 1-to-1 multiplexer to the second sense amplifier placed in another layout portion including the second active area.

4. The method of claim 2, wherein the active areas formed along the row direction comprises a first active area located within a first cell column and a second cell column adjacent to each other; the method further comprises:
forming a first pair of metal lines in the first cell column;
forming a second pair of metal lines in the second cell column; and
coupling the first pair of metal lines and the second pair of metal lines via metal contacts within the first active area, thereby constructing a pair of conductive lines;
wherein the pair of conductive lines are adapted to transmit a data signal of the X-to-1 multiplexer circuit to a sense amplifier placed in a layout portion including the first active area.

5. The method of claim 2, wherein the active areas formed along the row direction comprises a first active area and a second active area, the first active area located within a first cell column and a second cell column adjacent to each other, and the second active area located within a third cell column and a fourth cell column adjacent to each other; wherein the second cell column is located between the first cell column and the third cell column; the method further comprises:
forming a first pair of metal lines in the first cell column;
forming a second pair of metal lines in the second column;
forming a third pair of metal lines in the third cell column;
forming a fourth pair of metal lines in the fourth column; and
coupling the first pair of metal lines, the second pair of metal lines, the third pair of metal lines and the fourth pair of metal lines via metal contacts within the first active area and the second active area respectively, thereby constructing a pair of conductive lines;
wherein the pair of conductive lines are adapted to transmit a data signal of the X-to-1 multiplexer circuit to a sense amplifier placed in a layout portion including the first active area and the second active area.

6. The method of claim 2, wherein the active areas formed along the row direction comprises a first active area and a second active area; wherein the first active area is located within a first cell column and a second cell column adjacent to each other, and the second active area is located within a third cell column and a fourth cell column adjacent to each other; wherein the second cell column is located between the first cell column and the third cell column; the step of arranging the gate structures on the active areas comprises:
arranging a first gate structure on the first active area; and
arranging a second gate structure separated from the first gate structure on the second active area, wherein the first gate structure and the second gate structures are electrically connected, and are arranged mirror-symmetrically with respect to a boundary between the second cell column and the third cell column.

7. The method of claim 1, wherein the step of arranging the gate structures on the active areas comprises:
arranging a plurality of gate structures on each active area to form a plurality of first transistors connected in parallel; and
arranging a plurality of gate structures on the active area to form a plurality of second transistors connected in parallel, wherein the gate structures of the first transistors are interleaved with the gate structures of the second transistors.

8. The method of claim 1, wherein the step of arranging the gate structures on the active areas comprises:
arranging a plurality of gate structures on each active area to form a plurality of first transistors connected in parallel;
arranging a plurality of gate structures on the active area to form a plurality of second transistors connected in parallel;
arranging a plurality of gate structures on the active area to form a plurality of third transistors connected in parallel; and
wherein the gate structures of the first transistors and the gate structures of the second transistors are placed between two of the gate structures of the third transistors.

9. A memory device, comprising:
a substrate, having a first cell column and a second cell column adjacent to each other;
a first column of memory cells, arranged in the first cell column along a column direction, the first column of memory cells being coupled to a first pair of bitlines;
a second column of memory cells, arranged in a second cell column along the column direction, the second column of memory cells being coupled to a second pair of bitlines;
a first 1-to-1 multiplexer circuit, configured to couple the first pair of bitlines to a first pair of metal lines arranged in the first cell column;
a second 1-to-1 multiplexer circuit, configured to couple the second pair of bitlines to a second pair of metal lines arranged in the second cell column; and
a first sense amplifier, configured to sense a data signal that is carried on the first pair of metal lines, the first sense amplifier comprising a first active area formed in the substrate, the first active area extending across a boundary between the first cell column and the second cell column, wherein the first sense amplifier is coupled to the first pair of metal lines via a group of contacts within the first active area.

10. The memory device of claim 9, further comprising:
a second sense amplifier configured to sense a data signal that is carried on the second pair of metal lines, the second sense amplifier having a second active area formed in the substrate, the second active area extending across the boundary between the first cell column and the second cell column, wherein the second active area is spaced apart from the first active area, and the second sense amplifier is coupled to the second pair of metal lines via another group of contacts within the second active area.

11. The memory device of claim 10, wherein each of the first pair of metal lines and the second pair of metal lines extends across the first active area and the second active area along the column direction.

12. The memory device of claim 9, wherein the first sense amplifier comprises:
a plurality of first transistors connected in parallel, each of which has a first source/drain region and a second source/drain region, wherein the first source/drain region of each first transistor is coupled to a first metal line of the first pair of metal lines, and the second source/drain region of the first transistor is coupled to a circuit node;
a plurality of second transistors connected in parallel, each of which has a first source/drain region and a second source/drain region, wherein the first source/drain region of each second transistor is coupled to a second metal line of the first pair of metal lines, and the second source/drain region of the second transistor is coupled to the circuit node; and
a plurality of third transistors connected in parallel, each of which has a first source/drain region and a second source/drain region, wherein the first source/drain region of each third transistor is coupled to the circuit node, and the second source/drain region of the third transistor is coupled to a reference voltage;
wherein respective gate structures of the first transistors, the second transistors and the third transistors are arranged in parallel across the first active area along a row direction substantially perpendicular to the column direction.

13. The memory device of claim 12, wherein the gate structures of the first transistors and the gate structures of the second transistors are placed between two of the gate structures of the third transistors.

14. The memory device of claim 12, wherein the gate structures of the first transistors are interleaved with the gate structures of the second transistors.

15. A memory device, comprising:
a substrate having a first cell column, a second cell column, a third cell column, and a fourth cell column arranged in parallel, wherein the first cell column is adjacent to the second cell column, and the third cell column is adjacent to the fourth cell column;
a first column of memory cells, arranged in the first cell column and coupled to a first pair of bitlines;
a second column of memory cells, arranged in the second cell column and coupled to a second pair of bitlines;
a third column of memory cells, arranged in the third cell column and coupled to a third pair of bitlines;
a fourth column of memory cells, arranged in the fourth cell column and coupled to a fourth pair of bitlines;
a 4-to-1 multiplexer circuit, configured to select one pair of bitlines from among the first pair of bitlines, the second pair of bitlines, the third pair of bitlines and the fourth pair of bitlines, and couple the selected bitline pair to a pair of output nodes; and
a sense amplifier, configured to sense a data signal on the output nodes, the sense amplifier having a first active area and a second active area separated from each other, wherein each of the first active area and the second active area is formed in the substrate and coupled to the output nodes; the first active area is formed across a boundary between the first cell column and the second cell column, and the second active area is formed across a boundary between the third cell column and the fourth cell column.

16. The memory device of claim 15, wherein:
an upper edge and a lower edge of the first active area are located within the first cell column and the second cell column, respectively, and an upper edge and a lower edge of the second active area are located within the third cell column and the fourth cell column, respectively.

17. The memory device of claim 15, wherein the sense amplifier comprises a plurality of transistors, and respective gate structures of the transistors are electrically connected while separated from each other;
wherein a portion of the gate structures are arranged in parallel on the first active area, and extend across the first active area along a direction substantially perpendicular to the boundary between the first cell column and the second cell column; another portion of the gate structures are arranged in parallel on the second active area, and extend across the second active area along a direction substantially perpendicular to the boundary between the third cell column and the fourth cell column.

18. The memory device of claim 17, wherein the portion of the gate structures arranged on the first active area and the portion of the gate structures arranged on the second active area are laid out mirror-symmetrically with respect to a boundary between the second cell column and the third cell column.

19. The memory device of claim 15, wherein the sense amplifier comprises:
a plurality of first transistors connected in parallel, each of which has a first source/drain region and a second source/drain region, wherein the first source/drain region of each first transistor is coupled to a first output node of the output node pair, and the second source/drain region of the first transistor is coupled to a circuit node; a gate structure of one of the first transistors is formed on the first active area, and a gate structure of another of the first transistors is formed on the second active area;
a plurality of second transistors connected in parallel, each of which has a first source/drain region and a second source/drain region, wherein the first source/drain region of each second transistor is coupled to a second output node of the output node pair, and a second source/drain region of the second transistor is coupled to the circuit node; a gate structure of one of the second transistors is formed on the first active area, and a gate structure of another of the second transistors is formed on the second active area; and
a plurality of third transistors connected in parallel, each of which has a first source/drain region and a second source/drain region, wherein the first source/drain region of each third transistor is coupled to the circuit node, and the second source/drain region of the third transistor is coupled to a reference voltage; a gate structure of one of the third transistors is formed on the first active area, and a gate structure of another of the third transistors is formed on the second active area.

20. The memory device of claim 19, wherein each gate structure of the first transistors and each gate structure of the second transistors are placed between two gate structures of the third transistors.
